(19) United States
(12) Patent Application Publication
(10) Pub. No.: US 2019/0326139 A1
(43) Pub. Date: Oct. 24, 2019

(54) CERAMIC WAFER HEATER HAVING COOLING CHANNELS WITH MINIMUM FLUID DRAG

(71) Applicant: Applied Materials, Inc., Santa Clara, CA (US)

(72) Inventor: Paul F. FORDERHASE, Austin, TX (US)

(21) Appl. No.: 16/389,677

(22) Filed: Apr. 19, 2019

Related U.S. Application Data
(60) Provisional application No. 62/660,938, filed on Apr. 21, 2018.

(51) Int. Cl. H01L 21/67; H01J 37/32; H01L 21/683

(52) U.S. Cl. CPC H01L 21/67109; H01L 21/67248; H01L 21/6833; H01J 37/32724

(57) ABSTRACT

Embodiments of the present disclosure generally provide apparatus and methods for cooling a substrate support. In one embodiment the present disclosure provides an electrostatic chuck for a processing system. The electrostatic chuck includes a cylindrical body having a heater element, a clamping electrode and spiral fluid channel in the cylindrical body, the spiral fluid channel fluidly connected to a compressor.

### CROSS-REFERENCE TO RELATED APPLICATIONS

This application claims benefit of U.S. provisional patent application Ser. No. 62/660,938, filed Apr. 21, 2018, which is hereby incorporated herein by reference.

### BACKGROUND

### Field

Embodiments of the present disclosure generally relate to semiconductor substrate processing systems. More specifically, embodiments of the disclosure relate to a method and apparatus for controlling temperature of a substrate in a semiconductor substrate processing system.

### Description of the Related Art

In the manufacture of integrated circuits, precise control of various process parameters is achieves consistent process results on an individual substrate, as well as process results that are reproducible from substrate to substrate. As the geometry limits of the structures for forming semiconductor devices are pushed against technology limits, tighter tolerances and precise process control facilitate fabrication success. However, with shrinking device and feature geometries, more precise critical dimension requirements and higher processing temperatures, chamber process control has become increasingly difficult. During high temperature processing, changes in the temperature and/or temperature gradients across the substrate may reduce deposition uniformity, material deposition rates, step coverage, feature taper angles, and other process parameters and results on semiconductor devices.

A substrate support pedestal is predominantly utilized to control the temperature of a substrate during processing, generally through control of backside gas distribution and the heating and cooling of the pedestal itself, and thus heating or cooling of a substrate on the support. Although conventional substrate pedestals have proven to be robust performers at larger substrate critical dimension requirements and lower substrate process temperatures, improvements in existing techniques for controlling the substrate temperature distribution across the diameter of the substrate will enable fabrication of next generation structures using higher processing temperatures.

Therefore, there is a need in the art for an improved method and apparatus for controlling temperature of a substrate during high temperature processing of the substrate in a semiconductor substrate processing apparatus.

### SUMMARY

Embodiments of the present disclosure generally provide apparatus and methods for cooling a substrate support. In one embodiment the present disclosure provides an electrostatic chuck for a substrate processing chamber. The electrostatic chuck includes a cylindrical body having a heater element, a clamping electrode and spiral fluid channel in the cylindrical body, the spiral fluid channel fluidly connected to a compressor.

In one embodiment the present disclosure provides a substrate support for a substrate processing chamber. The substrate support includes an electrostatic chuck having a heater element, a clamping electrode and spiral fluid channel, the spiral fluid channel fluidly connected to a compressor.

In one embodiment the present disclosure provides a substrate support for a substrate processing chamber. The substrate support includes a pedestal assembly and an electrostatic chuck. The electrostatic chuck having a heater element, a clamping electrode and spiral fluid channel, the spiral fluid channel fluidly connected to a compressor.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a sectional schematic diagram of a semiconductor substrate processing apparatus comprising a substrate pedestal in accordance with one embodiment disclosed herein.

FIG. 2 is a schematic depiction of a closed loop fluid supply source in accordance with one embodiment disclosed herein.

FIG. 3 is a top plan view of a cross-section of a cooling channel layout in the electrostatic chuck shown in FIG. 1, taken across line 3-3, in accordance with one embodiment disclosed herein.

FIG. 4 is a top plan view of a cross-section of an alternative cooling channel layout of the electrostatic chuck shown in FIG. 3, in accordance with one embodiment disclosed herein.

FIG. 5 is a top plan view of a cross-section of alternative cooling channel layout of the electrostatic chuck shown in FIGS. 3 and 4, in accordance with one embodiment disclosed herein.

### DETAILED DESCRIPTION

The present disclosure generally provides a method and apparatus for controlling temperature of a substrate during processing thereof in a high temperature environment. Although the disclosure is illustratively described with respect to a semiconductor substrate plasma processing apparatus including plasma etch and plasma deposition processes, the subject matter of the disclosure may be utilized in other processing systems, including non-plasma etch, deposition, implant and thermal processing, or in other application where control of the temperature profile of a substrate or other workpiece is desirable.

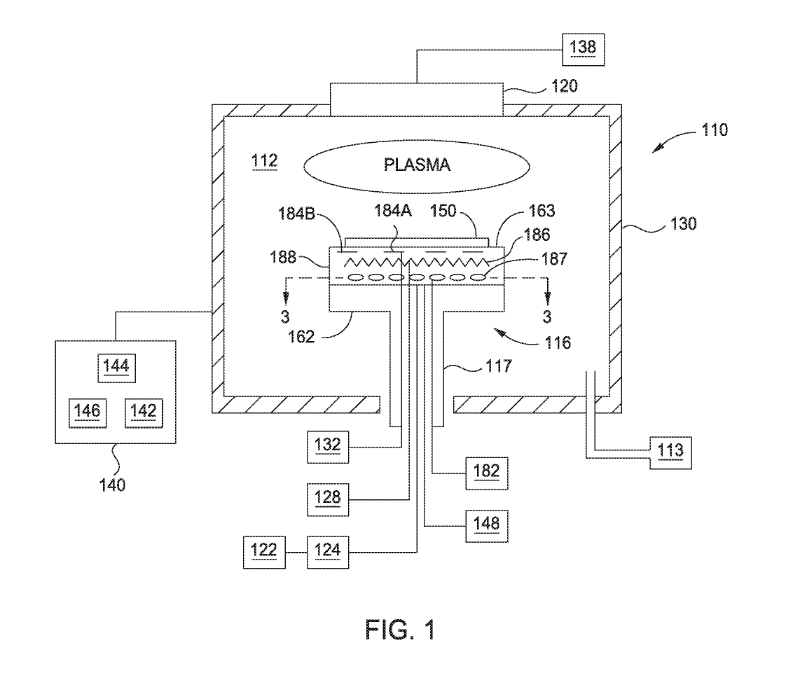

FIG. 1 depicts a schematic view of a substrate processing system 100 having one embodiment of a substrate support assembly 116 having an integrated pressurized cooling system 182. The particular embodiment of the substrate processing system 100 shown herein is provided for illustrative purposes and should not be used to limit the scope of the disclosure.

Substrate processing system 100 generally includes a process chamber 110, a gas panel 138 and a system controller 140. The process chamber 110 includes a chamber body (wall) 130 and a showerhead 120 that enclose a process volume 112. Process gasses from the gas panel 138 are provided to the process volume 112 of the process chamber 110 through the showerhead 120. A plasma may be created in the process volume 112 to perform one or more processes on a substrate held therein. The plasma is, for example, created by coupling power from a power source (e.g., RF power source 122) to a process gas via one or more electrodes (described below) within the chamber process volume 112 to ignite the process gas and create the plasma.

The system controller 140 includes a central processing unit (CPU) 144, a memory 142, and support circuits 146. The controller 140 is coupled to and controls components of the substrate processing system 100 to control processes performed in the process chamber 110, as well as may facilitate an optional data exchange with databases of an integrated circuit fab.

The process chamber 110 is coupled to and in fluid communication with a vacuum system 113, which may include a throttle valve (not shown) and vacuum pump (not shown) which are used to exhaust the process chamber 110. The pressure within the process chamber 110 may be regulated by adjusting the throttle valve and/or vacuum pump, in conjunction with gas flows into the chamber process volume 112.

The substrate support assembly 116 is disposed within the interior chamber process volume 112 for supporting and chucking a substrate 150, such as a semiconductor wafer or other such substrate as may be electrostatically retained. The substrate support assembly 116 generally includes a pedestal assembly 162 for supporting electrostatic chuck 188. The pedestal assembly 162 includes a hollow support shaft 117 which provides a conduit for piping to provide gases, fluids, heat transfer fluids, power, or the like to the electrostatic chuck 188.

The electrostatic chuck 188 is generally formed from ceramic or similar dielectric material and comprises at least one clamping electrode 186 controlled using a power supply 128. In a further embodiment, the electrostatic chuck 188 may comprise at least one RF electrode (not shown) coupled, through a matching network 124, to an RF power source 122. The electrostatic chuck 188 may optionally comprise one or more substrate heaters. In one embodiment, two concentric and independently controllable resistive heaters, shown as concentric heater elements 184A, 184B, coupled to power source 132, are utilized to control the edge to center temperature profile of the substrate 150.

The electrostatic chuck 188 further includes a plurality of gas passages (not shown), such as grooves, that are formed in a substrate supporting surface 163 of the electrostatic chuck 188 and fluidly coupled to a source 148 of a heat transfer (or backside) gas. In operation, the backside gas (e.g., helium (He)) is provided at a controlled pressure into the gas passages to enhance the heat transfer between the electrostatic chuck 188 and the substrate 150. In some examples, at least the substrate supporting surface 163 of the electrostatic chuck 188 is provided with a coating resistant to the chemistries and temperatures used during processing of the substrates.

The electrostatic chuck 188 includes one or more cooling channels 187 that are coupled to the cooling system 182. A heat transfer fluid, which may be at least one gas such as Freon, Argon, Helium or Nitrogen, among others, or a liquid such as water, Galvan, or oil, among others, is provided by the cooling system 182 through the cooling channels 187. The heat transfer fluid is provided at a predetermined temperature and flow rate to control the temperature of the electrostatic chuck 188 and to control, in part, the temperature of a substrate 150 disposed on the substrate support assembly 116. The temperature of the substrate support 116 is controlled to maintain the substrate at a desired temperature, or change the substrate 150 temperature between desired temperatures during processing. The cooling channels 187 may be fabricated into the electrostatic chuck 188 below heater elements 184A and 184B, clamping electrode 186 and RF electrode (not shown). Alternatively, in one example, the cooling channels 187 are disposed in the pedestal assembly 162, below the electrostatic chuck 188.

Cooling fluid is routed through cooling channels 187 to remove excess heat from the electrostatic chuck 188. Heat is generated by the plasma within the processing volume 112 and is absorbed by the substrate and thus the electrostatic chuck 188. In one embodiment, helium is used as the cooling fluid, particularly because helium is very effective at heat transfer when the plasma is a high temperature plasma using large amounts of RF energy to sustain the plasma above the substrate 150. Helium as a cooling gas has a number of advantages over other cooling mediums. For example, helium can be used for high temperature applications because helium, at temperatures greater than 4 degrees Kelvin has no temperature limitations such as a boiling point that limits the amount of heat transfer, as compared to water, which has a boiling point at 100 degrees Celsius. Additionally, helium is readily available within a wafer processing environment and is neither flammable nor toxic.

Temperature of the substrate support assembly 116, and hence the substrate 150, is monitored using a plurality of sensors (not shown in FIG. 1). Routing of the sensors is through the pedestal assembly 162. The temperature sensors, such as a fiber optic temperature sensor, are coupled to the system controller 140 to provide a metric indicative of the temperature profile of the substrate support assembly 116 and electrostatic chuck 188.

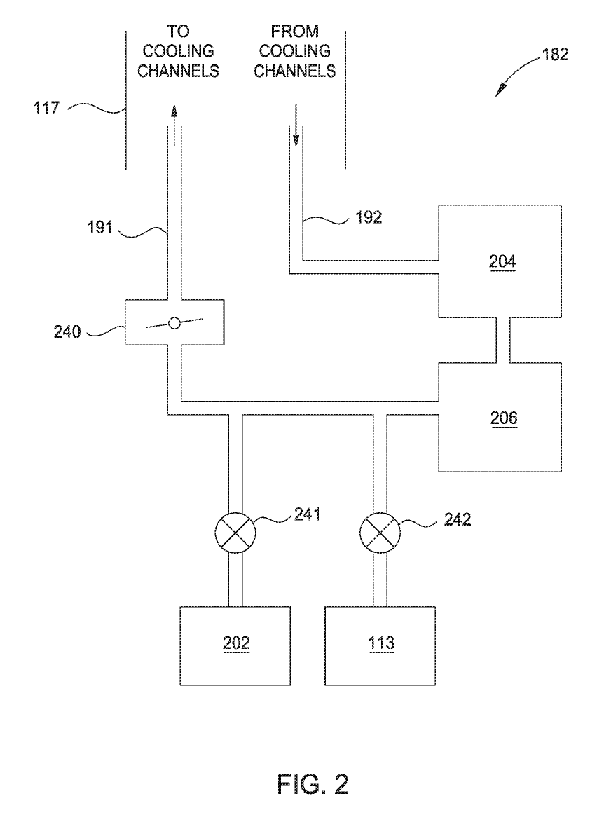

FIG. 2 is a schematic depiction of substrate support cooling system 182 shown in FIG. 1. In one embodiment, cooling system 182 is a closed loop fluid supply system used to provide a heat transfer fluid at a desired set point temperature and flow rate to the electrostatic chuck 188 during plasma processing. For example, when using helium as the heat transfer fluid for the electrostatic chuck 188, the helium coming from cooling channels 187 is cooled in the heat exchanger 204 and then is then routed again to the cooling channels 187 to cool, i.e., remove heat from, the electrostatic chuck 188. A non-closed loop system would cool the electrostatic chuck 188 by continually providing a helium gas at a set point temperature and flow rate from an external helium gas supply source and then discarding the heated helium gas once the heated helium has been through the cooling channels 187. By using the helium in a closed loop process, the amount and cost of the helium is limited, but also the temperature and flow rate of the helium routed to the electrostatic chuck 188 may be closely regulated resulting in increased control of the temperature set point of the electrostatic chuck 188 and the resulting process temperature of the substrate 150 thereon.

As shown in FIG. 2 and referring to FIG. 1, gas delivery conduit 191 and gas return conduit 192 are routed to and from the cooling channels 187 within electrostatic chuck 188 through the hollow support shaft 117 of pedestal assembly 162. An external helium supply source 202 is fluidly coupled to gas delivery conduit 191 to supply the helium gas to the cooling system 182. Control valve 241 is positioned between the external helium supply source 202 and the gas delivery conduit 191 to regulate the amount (flow rate) and the pressure of helium gas flow into the closed loop system.

In one embodiment, vacuum system 113 may be coupled to gas delivery conduit 191. As described above, vacuum system 113 includes a vacuum pump (not shown) used to exhaust the process chamber 110. By coupling the vacuum system 113 to the closed loop fluid supply, the system provides an existing source of vacuum to purge the closed loop system of air before the helium is introduced into the system from external helium supply source 202. By using the existing vacuum system 113, a separate purge vacuum is not required, or alternatively, gas from helium supply source 202 is not needed to purge the closed loop system of air. Control valve 242 is positioned between the vacuum system 113 and gas delivery conduit 191 to regulate the purge of the closed loop system.

Gas return conduit 192 delivers the heated gas from the cooling channels 187 within electrostatic chuck 188 via hollow support shaft 117 of pedestal assembly 162 (shown in FIG. 1) to the heat exchanger 204. Heat is removed from the helium gas by the heat exchanger 204. The heat exchanger 204 is coupled to facility cooling water (not shown) and the facility cooling water transfers the waste heat from the helium gas to the facility cooling water. The amount of heat removed from the helium gas is monitored and controlled by the system controller 140 (shown in FIG. 1). The system controller 140 regulates the heat exchanger 204 and thus the degree the helium gas is cooled based on the chamber process conditions including the temperature of the plasma, the temperature of the substrate support assembly 116 and the target processing temperature of the substrate 150, among others.

Compressor 206 is fluidly connected to the heat exchanger 204 and increases the pressure of the helium gas through the cooling channels 187 in the electrostatic chuck 188. It has been found that the heat transfer, i.e., the heat removal rate of heat from the electrostatic chuck into the helium gas, is increased by increasing the density of the helium gas. To facilitate the increased heat transfer, the compressor 206 provides an increased working pressure and provides the helium gas at a higher flow rate. By increasing the pressure of the helium gas, the mass flow rate is increased for any given volume flow rate. Because the mass flow rate of the helium gas, e.g., the change in density of helium in the gas flow changes the mass flow rate, governs the amount of heat removed by the helium gas, an increase in working pressure in the closed loop fluid supply system increases the heat removal rate by the ratio of working pressure to atmospheric pressure. The compressor 206 is used to increase the working pressure of the helium. The compressor is also used to maintain the working pressure and overcome the high head loss associated with the pressure drop of the helium gas due to the friction associated with the orientation of the conduits 191 and 192, cooling channels 187 and other cooling system components to pump the helium through the cooling system. The compressor 206 and the flow rate of the closed loop fluid supply system are controlled by the system controller 140 and are controlled in conjunction with the control of the temperature of the electrostatic chuck 188. Throttle valve 240 may be used to regulate the helium flow through the system, but alternatively, any manner of controlling flow may be used, such as driving the compressor via a DC motor or AC motor with a variable frequency drive. Both DC motors and variable frequency drives provide a variable motor speed and thus, a variable, controllable flow.

In operation, helium is supplied into the cooling system from source helium supply 202 to a desired pressure, and thus mass of helium per cubic centimeter (cc), in the cooling circuit, and then control valve 241 is closed to isolate helium supply source 202 from the cooling circuit. The helium gas is flowed by the pressure of the compressor 206 and is thus introduced to the cooling channels 187 within the electrostatic chuck 188 and the heater elements 184A and 184B (shown in FIG. 1) are energized to elevate the temperature of the electrostatic chuck 188 and substrate 150 to the target processing temperature. For example a target temperature of the electrostatic chuck may be between 200 degrees Celsius and 700 degrees Celsius, such as 300 degrees Celsius. When the electrostatic chuck temperature is reached, RF power is applied to strike a plasma within processing volume 112. As the substrate 150 and electrostatic chuck 188 absorb the heat energy from the plasma, the helium flow rate is controlled to maintain the desired operating temperature, i.e., the set point temperature, of the electrostatic chuck 188 and to prevent the electrostatic chuck 188 from overheating.

In one operation, the helium flow rate through the cooling channels 187 of the electrostatic chuck 188 is maintained at a constant flow rate to absorb the heat energy from the electrostatic chuck 188 while the energy to the heater elements 184A and 184B is variably controlled by the system controller 140 to maintain the desired operating target temperature of the electrostatic chuck 188 during processing.

In one operation, both the energy to the heater elements 184A and 184B of electrostatic chuck 188 and the helium flow rate through the cooling channels 187 of the electrostatic chuck 188 are variably controlled by the system controller 140 to provide the desired operating temperature or temperatures of the electrostatic chuck 188 during the operation processing window.

The arrangement of the helium supply source 202, the heat exchanger 204, compressor 206 and vacuum system 113 of cooling system 182 is for illustrative purposes only and need not be provided in the order and arrangement as shown in FIG. 2. Rather, the arrangement of these components may be in any order that efficiently fit within the chamber's system architecture, footprint and the desired locations within the fab and subfab as needed.

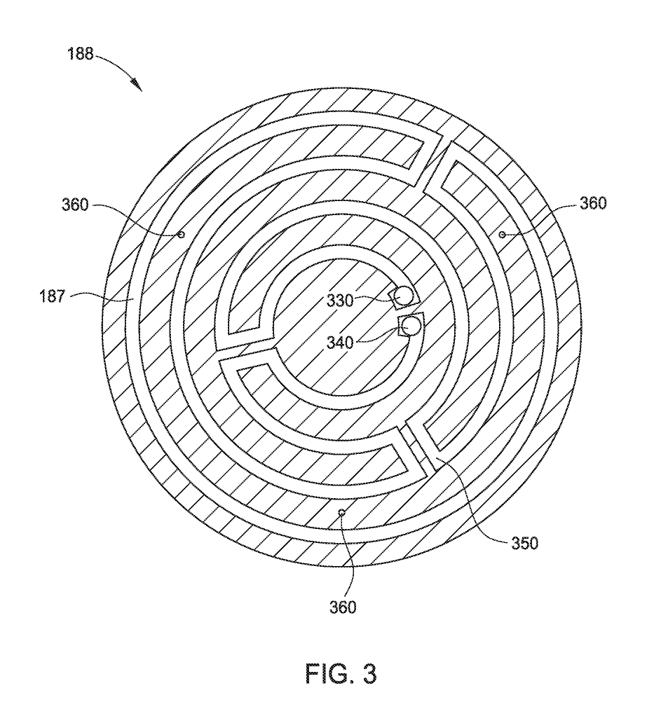

FIG. 3 illustrates one example of a plan view of electrostatic chuck 188 sectioned along horizontal line 3-3 of FIG. 1. A tortuous cooling channel 187 is present in the electrostatic chuck 188 and is dimensioned to pass a heat transfer fluid at a desired flow rate. As shown in FIG. 1, the cooling channel 187 is fabricated into the electrostatic chuck 188 below heater elements 184A and 184B, clamping electrode 186 and RF electrode (not shown). Alternatively, in one example, the cooling channel 187 is disposed in the pedestal assembly 162, below the electrostatic chuck 188. To facilitate uniform cooling across the chuck, the cooling channel 187 is formed into concentric segments extending approximately 340 to 350 degrees about the center of the electrostatic chuck 188. Each such segment is approximately evenly radially spaced from the adjacent segment(s), to form a continuous groove having a serpentine scheme. At the opposed ends of the cooling channel 187 nearest the center of the electrostatic chuck 188, the cooling fluid coming from inlet gas delivery conduit 191 (FIG. 2) enters the cooling channel 187 at a circular inlet port 330 and travels through the channel. As the cooling fluid travels through the channel, the cooling fluid absorbs heat from the electrostatic chuck 188. The cooling fluid then exits the channel at a circular port 340 to return via gas return conduit 192 to the cooling system 182 so that the cooling gas can be cooled and cycled again through the cooling channel 187. Corner 350 is one of 12 corners or abrupt changes in the fluid flow direction utilized by this particular serpentine pattern. Twelve or more changes in fluid flow direction, both radial and circumferential, are a typical number of direction changes for a spatially consistent cooling channel pattern intended to cover a cooling area of an electrostatic chuck. Each change of direction of the cooling channels imposes greater drag on the flow of the cooling fluid than the drag along the curved circumferential, and straight radial, segments of the cooling channel 187. The drag associated with this serpentine design inhibits the flow of the cooling gas, thus limiting the mass flow rate discussed above in reference to FIG. 2, thereby limiting the heat transfer capability of the cooling fluid for a given inlet pressure of the fluid at inlet port 330.

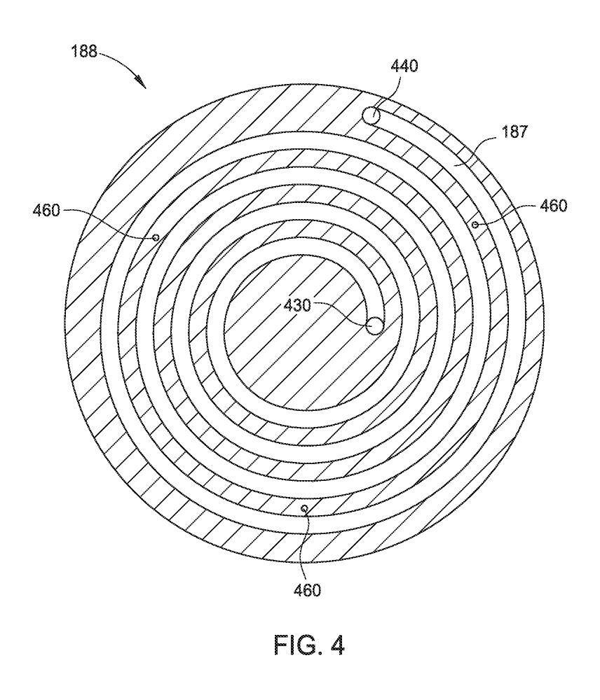

FIG. 4 illustrates a plan view of a cooling channel design that reduces the drag associated with the cooling channel design shown in FIG. 3, according to one embodiment of the disclosure. The cooling channel design allows for increased velocity of the flow of the cooling fluid, which in turn provides a higher heat transfer rate for the cooling fluid. It is understood that as the velocity of the cooling fluid increases, the drag created by the cooling fluid as it transits the cooling system increases. Therefore, it is beneficial to use a coolant channel design in the electrostatic chuck 188 that allows for an increased relative flow of the cooling fluid by reducing the additional drag associated with the abrupt changes in direction and yet still provide uniform cooling across the electrostatic chuck 188. Additionally, fluid flow in the cooling channels transitions from laminar flow to turbulent flow as the velocity in the cooling channels increases, and the film coefficient governing the heat transfer between the cooling fluid and the channel walls of the of the electrostatic chuck 188 increases once the coolant flow becomes turbulent.

As shown in FIG. 4, cooling channel 187 is a spiral design that has no abrupt changes in fluid flow direction, thereby reducing the drag and allowing increased cooling fluid flow velocity. The spiral pattern accommodates lift pin holes 460 and provides for a gradual change in flow direction that more closely relates to the drag associated with a straight section of the cooling channel because the cooling channel does not have any corners or abrupt changes in direction. In operation, the cooling fluid coming from inlet gas delivery conduit 191 (FIG. 2) enters the cooling channel 187 at circular port 430 and travels through the spiral channel at a high velocity providing a turbulent flow, absorbing heat from the electrostatic chuck 188, and exits the cooling channel 187 at circular port 440 returning via gas return conduit 192 to the cooling system 182 for the cooling gas to be cooled and cycled again through the cooling channels 187. It has been found that the drag imposed by this spiral design is a fraction of the drag inherent in a conventional pattern with multiple abrupt changes in flow direction shown in FIG. 3. The reduced drag allows for increased cooling fluid velocity resulting in turbulent flow which provides increased heat transfer from the electrostatic chuck 188 to the cooling fluid.

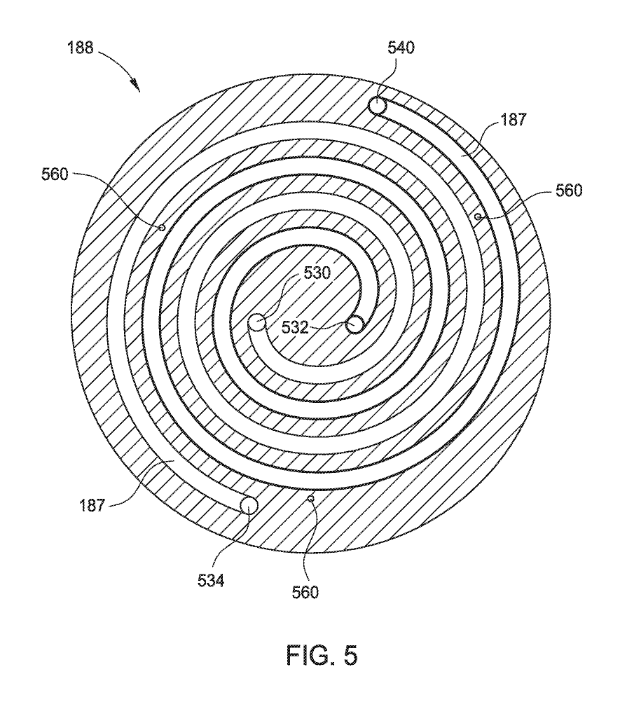

FIG. 5 illustrates a plan view of an interleaved two-spiral cooling channel design according to one embodiment of the disclosure. The two-spiral design shown in FIG. 5 accommodates 2 separate and interleaved spiral cooling channels 187. The double spiral pattern is located to accommodate lift pin holes 560 between adjacent channel locations and provides shorter channels and an even more gradual change in flow direction than the spiral design shown in FIG. 4 providing even less drag, resulting in further increased flow rate and heat transfer. In addition, because there are two separate spiral channels across the electrostatic chuck, the overall length of each of the cooling channels is shortened providing more uniform cooling from the center of the electrostatic chuck 188 to the outer perimeter of the chuck. In operation, the cooling fluid coming from inlet gas delivery conduit 191 (FIG. 2) enters the cooling channels 187 at circular ports 530 and 532 and travels through the respective spiral channels at high velocity providing a turbulent flow. As the cooling fluid travels, the cooling fluid absorbs heat from the electrostatic chuck 188. The cooling fluid then exits the channels at circular ports 540 and 542, returning via gas return conduit 192 to the cooling system 182 for the cooling gas to be cooled and cycled again through the cooling channels 187. The shortened length of the cooling channel allows less opportunity for the cooling gas to increase in temperature along the length of the cooling channel resulting in a more uniform temperature across the electrostatic chuck 188. In one embodiment, the number of spiral channels may not limited to one or two, but can include 3 or 4 channels, or more. In such an example, each channel may include an even more gradual change in flow direction, and each channel includes respective entrance and exit ports. Such a configuration further decreases the length of the cooling channels, yet providing spatial uniformity, and therefore temperature uniformity, across the electrostatic chuck 188.

While the foregoing is directed to embodiments of the present disclosure, other and further embodiments of the disclosure may be devised without departing from the basic scope thereof.

What is claimed is:

1. An electrostatic chuck for a substrate processing chamber, comprising:
a cylindrical body, comprising:
a heater element;
a clamping electrode; and
a spiral fluid channel in the cylindrical body, wherein the spiral fluid channel is fluidly connected to a compressor.

2. The electrostatic chuck of claim 1, wherein the spiral fluid channel is further fluidly connected to a cooling system comprising a heat exchanger.

3. The electrostatic chuck of claim 1, wherein the spiral fluid channel is further selectively fluidly connected to a cooling system comprising a vacuum system.

4. The electrostatic chuck of claim 3, wherein the vacuum system comprises a vacuum pump fluidly coupled to a processing chamber, within which the electrostatic chuck is located.

5. The electrostatic chuck of claim 1, wherein the spiral fluid channel is further fluidly connected to a closed loop cooling system.

6. The electrostatic chuck of claim 1, wherein the spiral fluid channel is further fluidly connected to a helium supply.

7. The electrostatic chuck of claim 1, wherein the compressor comprises a variable speed DC motor.

8. The electrostatic chuck of claim 1, wherein the compressor comprises an AC motor with a variable frequency drive.

9. The electrostatic chuck of claim 1, wherein the spiral fluid channel is further fluidly connected to a throttle valve.

10. A substrate support assembly for a substrate processing chamber, comprising:
an electrostatic chuck, comprising:
a heater element;
a clamping electrode; and
a spiral fluid channel, wherein the spiral fluid channel is fluidly connected to a compressor.

11. The substrate support assembly of claim 10, wherein the spiral fluid channel is further fluidly connected to a cooling system comprising a heat exchanger.

12. The substrate support assembly of claim 10, wherein the spiral fluid channel is further fluidly connected to a cooling system comprising a vacuum system.

13. The substrate support assembly of claim 12, wherein the vacuum system comprises a vacuum pump fluidly coupled to a processing chamber within which the electrostatic chuck is located.

14. The substrate support assembly of claim 10, wherein the spiral fluid channel is further fluidly connected to a closed loop cooling system.

15. The substrate support assembly of claim 10, wherein the spiral fluid channel is further fluidly connected to a helium supply.

16. The substrate support assembly of claim 10, wherein the compressor comprises a variable speed DC motor.

17. The substrate support assembly of claim 10, wherein the compressor comprises an AC motor with a variable frequency drive.

18. The substrate support assembly of claim 10, wherein the spiral fluid channel is further fluidly connected to a throttle valve.

19. A substrate support assembly for a substrate processing chamber, comprising:
a pedestal assembly;
an electrostatic chuck, comprising:
a heater element;
a clamping electrode; and
a spiral fluid channel, wherein the spiral fluid channel is fluidly connected to a compressor.

20. The substrate support assembly of claim 19, wherein the spiral fluid channel is further fluidly connected to a cooling system comprising a heat exchanger.
